(19) United States
(12) Patent Application Publication
(10) Pub. No.: US 2025/0183084 A1
(43) Pub. Date: Jun. 5, 2025

(54) SUBSTRATE PROCESSING APPARATUS AND SUBSTRATE PROCESSING METHOD USING THE SAME

(71) Applicant: Samsung Display Co., LTD., Yongin-si (KR)

(72) Inventors: YONGHYUN KIM, Yongin-si (KR); GYEONGHEE HAN, Yongin-si (KR); KYU-BUM KIM, Yongin-si (KR); SEUNGHO MYOUNG, Yongin-si (KR)

(21) Appl. No.: 18/947,737

(22) Filed: Nov. 14, 2024

(30) Foreign Application Priority Data
Nov. 30, 2023 (KR) 10-2023-0170955

(51) Int. Cl. H01L 21/683; H01L 21/677; H01L 21/68; H01L 21/687

(52) U.S. Cl. CPC H01L 21/6833; H01L 21/67778; H01L 21/681; H01L 21/68735

(57) ABSTRACT

A substrate processing apparatus includes: a stage including an electrostatic chuck, which chucks a substrate; a separating module disposed on the stage and including a push member, which separates the substrate from the electrostatic chuck, and a substrate holder, which supports an edge of the substrate; and a loading module disposed under the stage and including a plurality of edge loading units, which press the edge of the substrate toward the electrostatic chuck, and a plurality of central loading units, which press a portion of the substrate positioned inside from the edge of the substrate toward the electrostatic chuck.

This application claims to Korean Patent Application No. 10-2023-0170955, filed on Nov. 30, 2023, and all the benefits accruing therefrom under 35 U.S.C. § 119, the content of which in its entirety is herein incorporated by reference.

### BACKGROUND

### 1. Field

The present disclosure relates generally to a substrate processing apparatus. More particularly, the present disclosure relates to a substrate processing apparatus and a substrate processing method using the same.

### 2. Description of the Related Art

With the development of information technology, the importance of a display device, which is a connection medium between a user and information, has been highlighted. For example, the use of display devices such as liquid crystal display (“LCD”) device, organic light emitting display (“OLED”) device, plasma display panel (“PDP”) device, quantum dot display device or the like is increasing.

Among manufacturing processes of the display device, an etching process is a process of creating a desired shape by etching unnecessary portions of a surface of a substrate using physical or chemical methods. In general, the etching process may be performed by irradiating a laser beam to the substrate to etch the substrate. To perform the etching process, the substrate may be lifted by a loading module and may be chucked in an electrostatic chuck.

### SUMMARY

Embodiments provide a substrate processing apparatus which prevents damage to a display panel cell and effectively separates a substrate from an electrostatic chuck.

Embodiments provide a substrate processing method which prevents damage to a display panel cell and effectively separates a substrate from an electrostatic chuck.

A substrate processing apparatus according to an embodiment of the present disclosure includes: a stage including an electrostatic chuck, which chucks a substrate, a separating module disposed on the stage and including a push member, which separates the substrate from the electrostatic chuck, and a substrate holder, which supports an edge of the substrate, and a loading module disposed under the stage and including a plurality of edge loading units, which press the edge of the substrate toward the electrostatic chuck, and a plurality of central loading units which press a portion of the substrate positioned inside from the edge of the substrate toward the electrostatic chuck.

In an embodiment, when the push member separates the substrate from the electrostatic chuck, the push member may press the substrate toward the loading module.

In an embodiment, the push member may include a sensor, which measures an electrostatic force between the substrate and the electrostatic chuck.

In an embodiment, the separating module may further include a control portion, which controls a speed of the push member in response to the electrostatic force.

In an embodiment, the apparatus may further include a camera disposed under the stage and which measures an alignment mark of the substrate. The stage may be configured to align the substrate based on a position of the alignment mark.

In an embodiment, the substrate may include a first side extending in a first direction, a second side which contacts the first side and extends in a second direction intersecting the first direction, a third side which extends parallel to the first side and faces the first side, and a fourth side which extends parallel to the second side and faces the second side. The substrate holder may not support one of the first to fourth sides.

In an embodiment, the plurality of edge loading units may include a plurality of first edge loading units, which press the one side of the substrate not supported by the substrate holder, and a plurality of second edge loading units, which press sides of the substrate supported by the substrate holder.

In an embodiment, the substrate may include a first side extending in a first direction and a second side which contacts the first side and extends in a second direction intersecting the first direction. A length of the first side may be smaller than a length of the second side. The plurality of central loading units may include a plurality of first central loading units, which press a central portion of the substrate, and a plurality of second central loading units, which are spaced apart from the plurality of first central loading units in the second direction and in a direction opposite to the second direction.

In an embodiment, the plurality of first central loading units may be repeatedly disposed along the first direction. The plurality of second central loading units may be repeatedly disposed along the first direction. The plurality of second central loading units may be positioned symmetrical with respect to the plurality of first central loading units.

In an embodiment, the apparatus may further include an elastic member disposed at an end of each of the plurality of edge loading units, which contacts the substrate.

A substrate processing method according to an embodiment of the present disclosure includes transferring a substrate to be positioned under a stage, which includes an electrostatic chuck, raising a separating module, which is positioned on the stage and includes a push member and a substrate holder, and supporting an edge of the substrate with the substrate holder, aligning a position of the substrate by moving the stage, raising a plurality of central loading units, which are positioned under the stage, to press a portion of the substrate positioned inside from the edge of the substrate, and raising a plurality of edge loading units, which are positioned under the stage, to press the edge of the substrate, chucking the substrate to the electrostatic chuck, and separating the substrate from the electrostatic chuck by de-chucking the substrate from the electrostatic chuck and by pressing the substrate with the push member.

In an embodiment, the separating of the substrate from the electrostatic chuck may include measuring an electrostatic force between the substrate and the electrostatic chuck, and controlling a speed of the push member in response to the electrostatic force.

In an embodiment, the push member may include a sensor, which measures the electrostatic force. The separating module may further include a control portion, which controls the speed of the push member in response to the electrostatic force.

In an embodiment, the substrate may include a first side extending in a first direction, a second side which contacts the first side and extends in a second direction intersecting the first direction, a third side which extends parallel to the first side and faces the first side, and a fourth side which extends parallel to the second side and faces the second side. The substrate holder may not support one of the first to fourth sides in the supporting of the edge of the substrate with the substrate holder.

In an embodiment, the method may further include raising some of the plurality of edge loading units to support the one side of the substrate which is not supported by the substrate holder before the aligning of the position of the substrate.

In an embodiment, the substrate may include a first side extending in a first direction and a second side which contacts the first side and extends in a second direction intersecting the first direction. A length of the first side may be smaller than a length of the second side. The plurality of central loading units may include a plurality of first central loading units, which press a central portion of the substrate, and a plurality of second central loading units, which are spaced apart from the plurality of first central loading units in the second direction and in a direction opposite to the second direction.

In an embodiment, the plurality of first central loading units may be repeatedly disposed along the first direction. The plurality of second central loading units may be repeatedly disposed along the first direction. The plurality of second central loading units may be positioned symmetrical with respect to the plurality of first central loading units.

In an embodiment, the plurality of first central loading units may rise before the plurality of second central loading units rise in the raising of the plurality of central loading units.

In an embodiment, the separating of the substrate from the electrostatic chuck may include lowering the push member and raising the plurality of edge loading units toward the substrate, clamping the substrate by bringing the push member and the plurality of edge loading units into contact with the substrate at the edge of the substrate, and raising the plurality of central loading units to contact the substrate.

In an embodiment, in the clamping of the substrate, an impact applied to the substrate may be relieved by an elastic member disposed at an end of each of the plurality of edge loading units, which contacts the substrate.

A substrate processing apparatus according to an embodiment of the present disclosure may include a stage including an electrostatic chuck, which chucks a substrate, a separating module including a push member, which is disposed on the stage and separates the substrate from the electrostatic chuck, and a substrate holder, which supports an edge of the substrate, and loading units, which press the substrate.

As the substrate holder supports the edge of the substrate, a process of aligning the substrate may be performed before the substrate contacts the loading units. Accordingly, the loading units may not contact a cell area of the substrate in which display panel cells are disposed, but may contact a dummy area of the substrate, which is subsequently removed. As a result, the problem of the display panel cells being damaged due to contact with the loading units may be effectively prevented.

The push member may press the substrate toward the loading units. Accordingly, even when the substrate is not separated from the electrostatic chuck due to a residual electrostatic charge between the substrate and the electrostatic chuck, the substrate may be effectively separated from the electrostatic chuck by the push member pressing the substrate toward the loading units.

### BRIEF DESCRIPTION OF THE DRAWINGS

Illustrative, non-limiting embodiments will be more clearly understood from the following detailed description in conjunction with the accompanying drawings.

FIG. 1 is a cross-sectional view illustrating a substrate processing apparatus according to an embodiment of the present disclosure.

FIG. 2 is a perspective view illustrating the substrate processing apparatus of FIG. 1.

FIG. 3 is a perspective view illustrating a separating module included in the substrate processing apparatus of FIG. 1.

FIG. 4 is an enlarged perspective view of area ‘A’ of FIG. 3.

FIG. 5 is a flowchart illustrating a substrate processing method according to an embodiment of the present disclosure.

FIGS. 6, 7, 8, 9, 10, 11, 12, 13, 14, 15, 16, 17, and 18 are views illustrating the substrate processing method of FIG. 5.

FIG. 19 is a flowchart illustrating separating a substrate from an electrostatic chuck included in the substrate processing method of FIG. 5.

FIGS. 20, 21, 22, and 23 are cross-sectional views illustrating the separating the substrate from the electrostatic chuck of FIG. 19.

### DETAILED DESCRIPTION

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

It will be understood that when an element is referred to as being “on” another element or “connected to” another element, it can be directly on or directly connected to the other element or intervening elements may be present therebetween. In contrast, when an element is referred to as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

Hereinafter, embodiments of the present disclosure will be described in detail with reference to the accompanying drawings. The same reference numerals are used for the same components in the drawings, and redundant descriptions of the same components will be omitted.

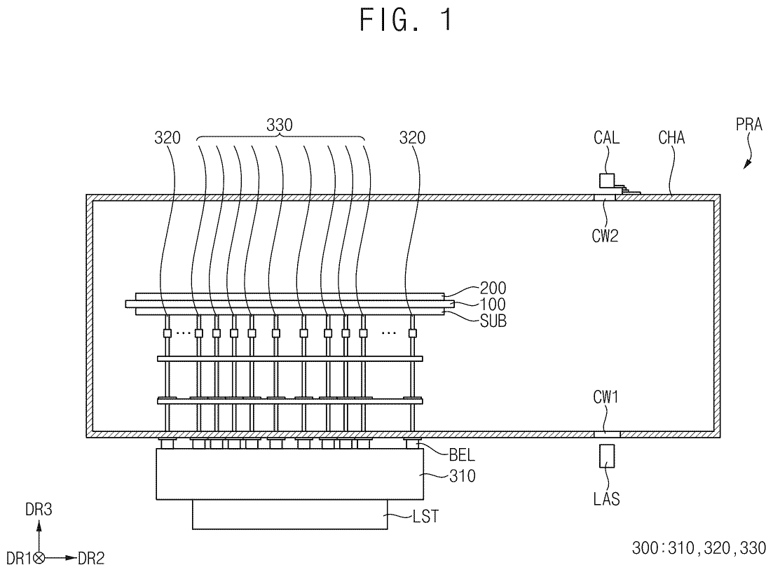

FIG. 1 is a cross-sectional view illustrating a substrate processing apparatus according to an embodiment of the present disclosure.

In this specification, a plane may be defined by a first direction DR1 and a second direction DR2 intersecting the first direction DR1. For example, the first direction DR1 and the second direction DR2 may be perpendicular to each other. A direction normal to the plane, that is, a thickness direction of a substrate SUB may be a third direction DR3. In other words, the third direction DR3 may be perpendicular to each of the first direction DR1 and the second direction DR2.

Referring to FIG. 1, a substrate processing apparatus PRA according to an embodiment of the present disclosure may include a chamber CHA, a stage 100, a separating module 200, a loading module 300, a loading stage LST, a laser unit LAS, and a laser measurement unit CAL.

In an embodiment, the substrate processing apparatus PRA may perform a process of etching the substrate SUB. Specifically, the substrate processing apparatus PRA may perform the process of etching the substrate SUB by radiating a laser beam to a lower portion of the substrate SUB.

The chamber CHA may define a space in which a process of processing the substrate SUB is performed. For example, the substrate SUB may be a substrate used in a display device, a semiconductor substrate, a solar cell substrate, etc. In an embodiment, the substrate SUB may be a substrate used in a display device. In this case, the substrate SUB may be a multi-faceted substrate including a plurality of display panel cells. The substrate SUB may include a cell area in which the display panel cells are disposed and a dummy area surrounding the cell area. The display panel cells may be manufactured into a display panel through a processing process. The dummy area may refer to an area of the substrate SUB which is removed through a later process.

A gate may be disposed on a side surface of the chamber CHA. The gate may serve as a passage through which the substrate SUB moves inside and outside the chamber CHA. The substrate SUB may be transferred into an interior of the chamber CHA through the gate using a substrate loading apparatus such as a transfer arm. The chamber CHA may have a cuboidal shape, but the present disclosure is not limited thereto.

A first chamber window CW1 may be disposed on a lower surface of the chamber CHA. The first chamber window CW1 may pass a laser beam of a specific wavelength. The first chamber window CW1 may pass a laser beam emitted from the laser unit LAS, which is disposed outside the chamber CHA, into the interior of the chamber CHA.

The laser unit LAS may be disposed outside the chamber CHA. For example, the laser unit LAS may be positioned adjacent to the lower surface of the chamber CHA. The laser unit LAS may irradiate the laser beam to the substrate SUB, which is positioned inside the chamber CHA, through the first chamber window CW1. The laser unit LAS may irradiate the laser beam to the substrate SUB to etch the substrate SUB.

A second chamber window CW2 may be disposed on an upper surface of the chamber CHA. The second chamber window CW2 may pass a laser beam of a specific wavelength. The second chamber window CW2 may pass a laser beam, which is positioned inside the chamber CHA, to the outside of the chamber CHA.

The laser measurement unit CAL may be disposed outside the chamber CHA. The laser measurement unit CAL may be positioned to face the laser unit LAS. For example, the laser measurement unit CAL may be positioned adjacent to the upper surface of the chamber CHA. The laser measurement unit CAL may receive the laser beam that has passed through the inside of the chamber CHA through the second chamber window CW2 and may measure the output of the laser beam. That is, the laser measurement unit CAL may check whether the laser unit LAS is malfunctioning by monitoring the output of the laser beam.

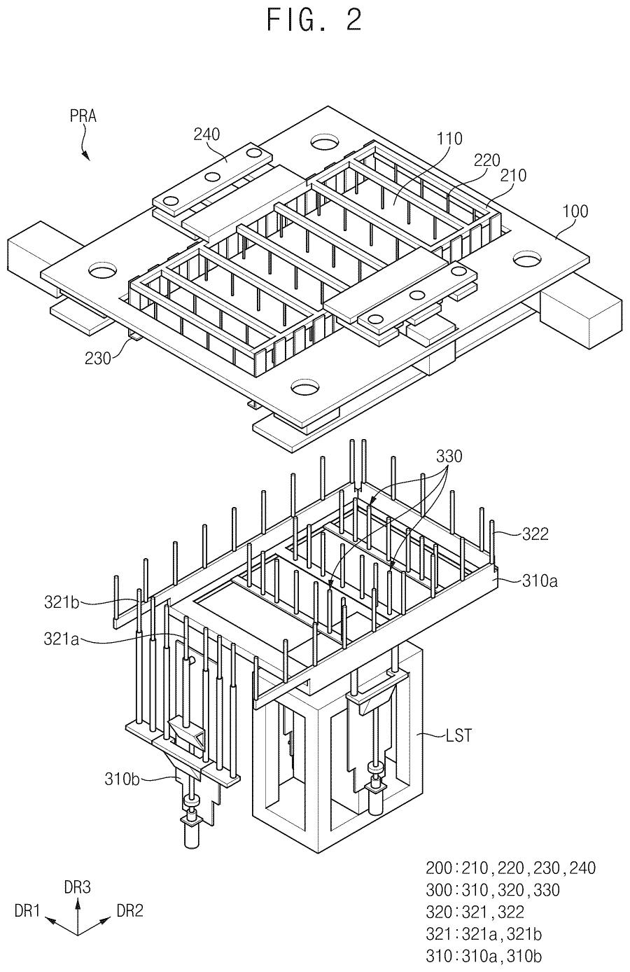

The stage 100 may be disposed inside the chamber CHA. The stage 100 may include an electrostatic chuck (e.g., an electrostatic chuck 110 of FIG. 2). The electrostatic chuck may chuck the substrate SUB with electrostatic force. Accordingly, the substrate SUB may be fixedly adsorbed to a lower surface of the electrostatic chuck. That is, the substrate SUB may be fixed with a surface that is irradiated by the laser beam facing downward.

The stage 100 may move in the second direction DR2 or in a direction opposite to the second direction DR2. Accordingly, the stage 100 may transfer the substrate SUB in the second direction DR2 toward the laser unit LAS. In addition, the stage 100 may transfer the substrate SUB toward the loading module 300 in the direction opposite to the second direction DR2.

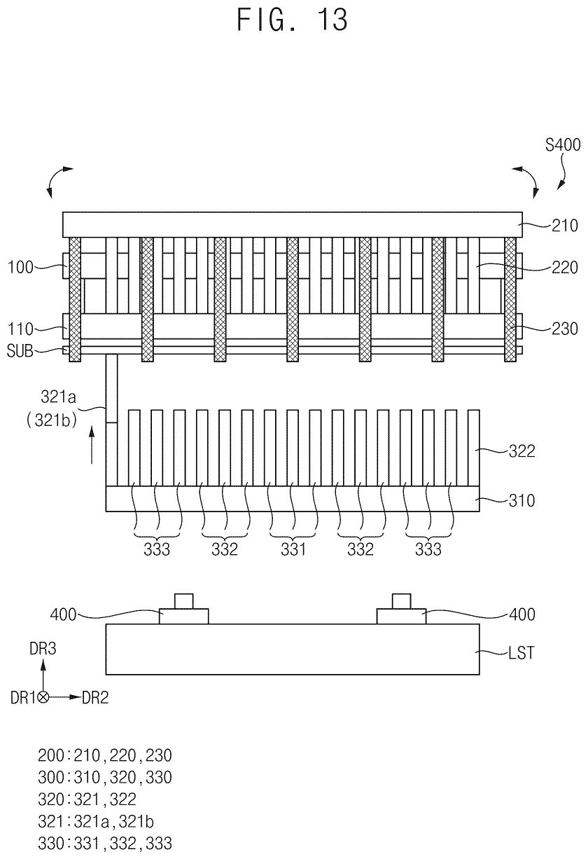

The stage 100 may align a position of the substrate SUB. Specifically, a camera (e.g., a camera 400 of FIG. 13) disposed under the stage 100 may measure an alignment mark of the substrate SUB, and the stage 100 may align the position of the substrate SUB, based on a position of the alignment mark. In an embodiment, for example, the stage 100 may be a UVW stage.

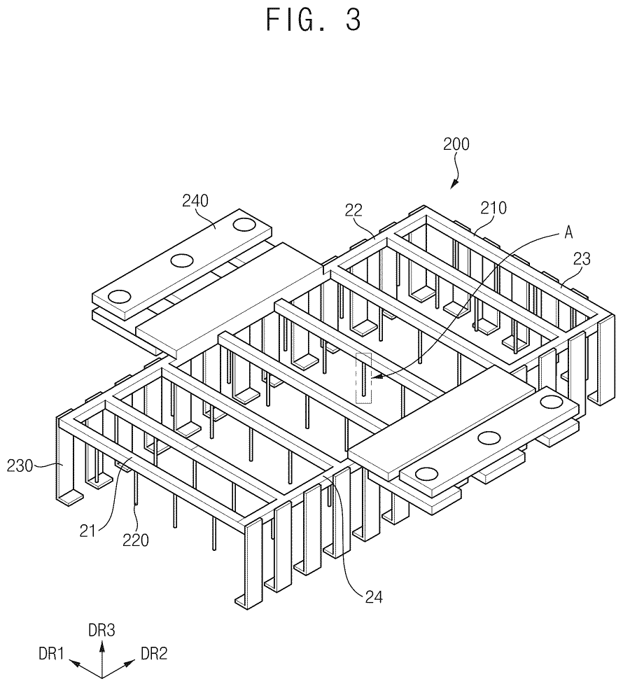

The separating module 200 may be disposed on the stage 100. The separating module 200 may include a first body portion (e.g., a first body portion 210 of FIG. 3), a push member (e.g., a push member 220 of FIG. 3), and a substrate holder (e.g., a substrate holder 230 of FIG. 3). The push member 220 may separate the substrate SUB from the electrostatic chuck 110 when unloading the substrate SUB. The substrate holder 230 may support an edge of the substrate SUB when aligning the position of the substrate SUB. A detailed description thereof will be provided below with reference to FIG. 3.

The loading stage LST may be disposed outside the chamber CHA. In an embodiment, for example, the loading stage LST may be positioned adjacent to the lower surface of the chamber CHA.

The loading module 300 may be disposed under the stage 100. The loading module 300 may include a second body portion 310, a plurality of edge loading units 320, a plurality of central loading units 330, and a bellows BEL. The second body portion 310 may be disposed outside the chamber CHA. In addition, the second body portion 310 may be disposed on an upper surface of the loading stage LST.

The edge loading units 320 and the central loading units 330 may be disposed under the stage 100. Specifically, the edge loading units 320 and the central loading units 330 may be disposed under the substrate SUB. The edge loading units 320 and the central loading units 330 may be connected to the second body portion 310. The edge loading units 320 and the central loading units 330 may penetrate the lower surface of the chamber CHA. The bellows BEL may surround each of the edge loading units 320 and each of the central loading units 330. The bellows BEL may seal the lower surface of the chamber CHA through which the edge loading units 320 and the central loading units 330 penetrate.

The edge loading units 320 may penetrate the lower surface of the chamber CHA and be positioned inside the chamber CHA. The edge loading units 320 may press (or support) the edge of the substrate SUB. Specifically, when chucking the substrate SUB to the electrostatic chuck, the edge loading units 320 may press the edge of the substrate SUB toward the electrostatic chuck from the lower portion of the substrate SUB. Although not illustrated in FIG. 1, the edge loading units 320 may be repeatedly disposed along the first direction DR1.

The edge loading units 320 may be connected to an edge loading driver. The edge loading driver may raise or lower the edge loading units 320. In other words, the edge loading driver may move the edge loading units 320 in the third direction DR3 or in a direction opposite to the third direction DR3.

The central loading units 330 may penetrate the lower surface of the chamber CHA and be positioned inside the chamber CHA. The central loading units 330 may press (or support) a portion of the substrate SUB which is positioned inside from the edge of the substrate SUB. Specifically, when chucking the substrate SUB to the electrostatic chuck, the central loading units 330 may press the portion of the substrate SUB, which is positioned inside from the edge of the substrate SUB, toward the electrostatic chuck from the lower portion of the substrate SUB.

As the central loading units 330 press the portion of the substrate SUB, sagging of the substrate SUB when the substrate SUB rises toward the electrostatic chuck may be prevented. Although not illustrated in FIG. 1, the central loading units 330 may be repeatedly disposed along the first direction DR1.

The central loading units 330 may be connected to a central loading driver. The central loading driver may raise or lower the central loading units 330. In other words, the central loading driver may move the central loading units 330 in the third direction DR3 or in the direction opposite to the third direction DR3.

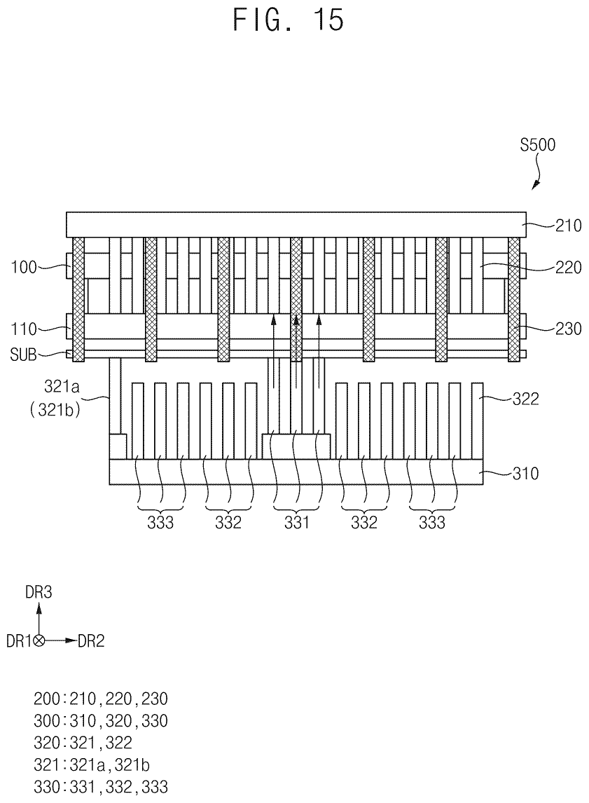

The central loading driver may drive the central loading units 330 in a time-divisible manner. In other words, the central loading driver may raise some of the central loading units 330 first and may raise other portions of the central loading units 330 later. A detailed description thereof will be provided below with reference to FIGS. 15, 16, and 17.

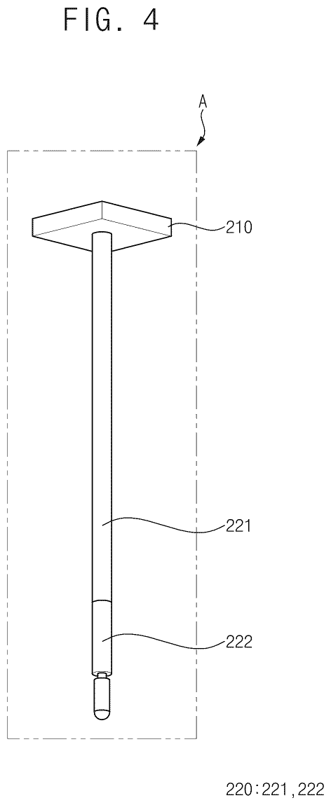

FIG. 2 is a perspective view illustrating the substrate processing apparatus of FIG. 1. FIG. 3 is a perspective view illustrating a separating module included in the substrate processing apparatus of FIG. 1. FIG. 4 is an enlarged perspective view of area ‘A’ of FIG. 3.

Referring to FIGS. 2, 3, and 4, the substrate processing apparatus PRA according to an embodiment of the present disclosure may include the stage 100, the separating module 200, the loading module 300, and the loading stage LST.

The stage 100 may include an electrostatic chuck 110. The electrostatic chuck 110 may chuck the substrate SUB with electrostatic force. Accordingly, the substrate SUB may be fixedly adsorbed to a lower surface of the electrostatic chuck 110. The stage 100 may align the position of the substrate SUB.

The separating module 200 may be disposed on the stage 100. The separating module 200 may include a first body portion 210, a push member 220, a substrate holder 230, and a coupling portion 240.

The first body portion 210 may be disposed on the stage 100. The first body portion 210 may configure a skeleton of the separating module 200. The first body portion 210 may have a ladder shape. Specifically, the first body portion 210 may include first portions each extending in the first direction DR1 and second portions each extending in the second direction DR2. The first portions may be spaced apart from each other in the second direction DR2. The second portions may be spaced apart from each other in the first direction DR1.

The push member 220 may be connected to the first body portion 210. The push member 220 may protrude from the first body portion 210 toward the electrostatic chuck 110. The push member 220 may penetrate the electrostatic chuck 110. In an embodiment, for example, the electrostatic chuck 110 may define a through hole corresponding to a position of the push member 220. The push member 220 may separate the substrate SUB from the electrostatic chuck 110. Specifically, the push member 220 may penetrate the electrostatic chuck 110 through the through hole and press the substrate SUB toward the loading module 300. The push member 220 may be repeatedly disposed along the first direction DR1 and the second direction DR2. Accordingly, the push member 220 may press the substrate SUB over the entire area of the substrate SUB.

In an embodiment, as illustrated in FIG. 4, the push member 220 may include a push body 221 and a sensor 222. The push body 221 may press the substrate SUB toward the loading module 300. That is, the push body 221 may directly contact the substrate SUB. In an embodiment, for example, the push body 221 may have a cylindrical shape, but the present disclosure is not limited thereto.

The sensor 222 may be disposed on the push body 221. In an embodiment, for example, the sensor 222 may be fixed to the push body 221 by a bracket. The sensor 222 may measure an electrostatic force between the substrate SUB and the electrostatic chuck 110. Specifically, the sensor 222 may measure the amount of residual electrostatic charge between the substrate SUB and the electrostatic chuck 110 after de-chucking the substrate SUB from the electrostatic chuck 110.

In an embodiment, the separating module 200 may further include a control portion which controls the speed of the push member 220 in response to the electrostatic force between the substrate SUB and the electrostatic chuck 110. Specifically, the control portion may control the speed of the push body 221 in response to the amount of residual electrostatic charge between the substrate SUB and the electrostatic chuck 110 which is measured by the sensor 222. In addition, the control portion may remove electrostatic charge between the substrate SUB and the electrostatic chuck 110 using vacuum ultraviolet (“VUV”). The control portion may include a microprocessor, a motor and a VUV light generator.

The substrate holder 230 may be connected to the first body portion 210. The substrate holder 230 may be repeatedly disposed along a circumference of the first body portion 210. The first body portion 210 may include a first side 21 extending in the first direction DR1, a second side 22 which contacts the first side 21 and extends in the second direction DR2, a third side 23 which extends parallel to the first side 21 and faces the first side 21, and a fourth side 24 which extends parallel to the second side 22 and faces the second side 22. In this case, the substrate holder 230 may not be disposed at one of the first to fourth sides 21, 22, 23, and 24 of the first body portion 210 so that the substrate SUB may be transferred under the stage 100. For example, as illustrated in FIGS. 2 and 3, the substrate holder 230 may be disposed at the second to fourth sides 22, 23, and 24 of the first body portion 210 and may not be disposed at the first side 21 of the first body portion 210. The substrate holder 230 may support an edge of the substrate SUB when aligning the position of the substrate SUB.

The coupling portion 240 may be connected to the first body portion 210. The first body portion 210 may be coupled to the stage 100 through the coupling portion 240. The separating module 200 may be connected to a separating module driver. The separating module driver may raise or lower the separating module 200. In other words, the separating module driver may move the separating module 200 in the third direction DR3 or in the direction opposite to the third direction DR3. By the separating module driver, the first body portion 210, the push member 220, and the substrate holder 230 may rise or descend simultaneously.

The loading module 300 may be disposed under the stage 100. In addition, the loading module 300 may be disposed on the loading stage LST. The loading module 300 may include the second body portion 310, the plurality of edge loading units 320, and the plurality of central loading units 330.

The second body portion 310 may be disposed under the stage 100. The second body portion 310 may configure a skeleton of the loading module 300. The second body portion 310 may include a first portion 310a and a second portion 310b. The first portion 310a of the second body portion 310 may have a rectangular shape with one side open in a plan view. The second portion 310b of the second body portion 310 may overlap the open side of the first portion 310a in a plan view. As used herein, the “plan view” is a view in a thickness direction (i.e., third direction DR3) of a substrate SUB.

The first portion 310a and the second portion 310b of the second body portion 310 may be driven in a time-divisible manner. In an embodiment, for example, the second portion 310b of the second body portion 310 may rise first, and the first portion 310a of the second body portion 310 may rise later. However, the present disclosure is not limited thereto, and the first portion 310a and the second portion 310b of the second body portion 310 may be driven simultaneously in another embodiment. In an embodiment, for example, the first portion 310a and the second portion 310b of the second body portion 310 may descend simultaneously.

The edge loading units 320 may include first edge loading units 321 and second edge loading units 322. The first edge loading units 321 may be connected to the second portion 310b of the second body portion 310. The first edge loading units 321 may protrude from the second portion 310b of the second body portion 310 toward the electrostatic chuck 110. The first edge loading units 321 may press (or support) one side of the substrate SUB (e.g., first side 11) which is not supported by the substrate holder 230.

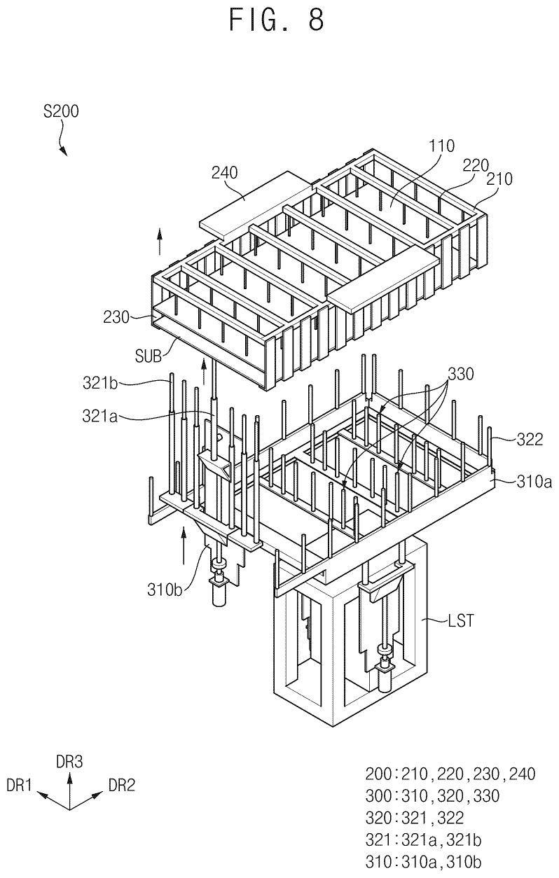

The first edge loading units 321 may include a (1-1)-th edge loading unit 321a and a (1-2)-th edge loading unit 321b. The (1-1)-th edge loading unit 321a and the (1-2)-th edge loading unit 321b may be driven in time-divisible manner. In an embodiment, for example, the (1-1)-th edge loading unit 321a may rise first, and the (1-2)-th edge loading unit 321b may rise later. However, the present disclosure is not limited thereto, and the (1-1)-th edge loading unit 321a and the (1-2)-th edge loading unit 321b may be driven simultaneously in another embodiment. For example, the (1-1)-th edge loading unit 321a and the (1-2)-th edge loading unit 321b may descend simultaneously. A detailed description thereof will be provided below with reference to FIGS. 8, 9, 10, and 11.

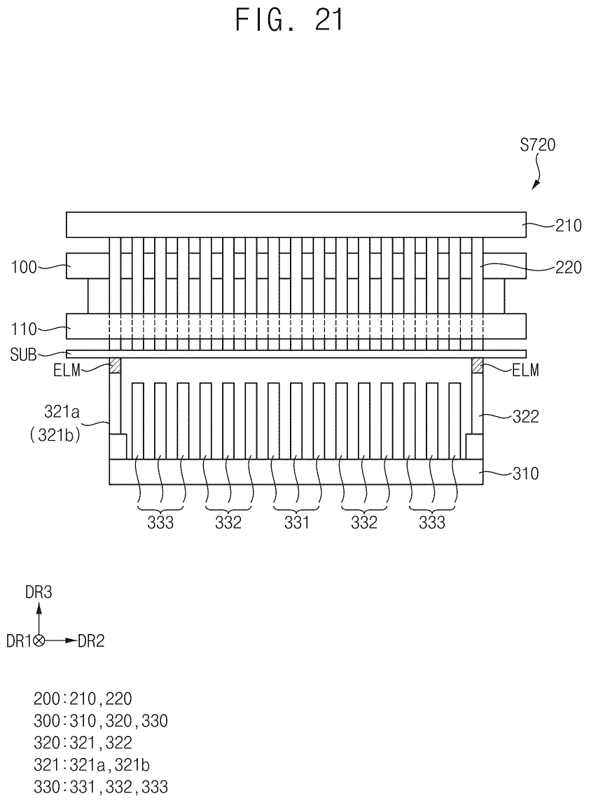

The second edge loading units 322 may be connected to the first portion 310a of the second body portion 310. The second edge loading units 322 may be repeatedly disposed along a circumference of the first portion 310a of the second body portion 310. The second edge loading units 322 may protrude from the first portion 310a of the second body portion 310 toward the electrostatic chuck 110. The second edge loading units 322 may press (or support) the sides of the substrate SUB which are supported by the substrate holder 230. Accordingly, the edge loading units 320 may press (or support) the edge of the substrate SUB toward the electrostatic chuck 110. In an embodiment, an elastic member (e.g., an elastic member ELM of FIG. 21) may be disposed at an end of each of the edge loading units 320. The end of each of the edge loading units 320 may refer to a portion which contacts the substrate SUB. The elastic member may relieve an impact applied to the substrate SUB when the edge loading units 320 contact the substrate SUB. A detailed description thereof will be provided below with reference to FIG. 21.

The central loading units 330 may be connected to the first portion 310a of the second body portion 310. The central loading units 330 may be disposed inside an edge of the first portion 310a of the second body portion 310. The central loading units 330 may protrude from the first portion 310a of the second body portion 310 toward the electrostatic chuck 110. The central loading units 330 may press (or support) a portion of the substrate SUB positioned inside from the edge of the substrate SUB. As illustrated in FIG. 2, the central loading units 330 may include three groups disposed in a row along the first direction DR1, and the groups may be spaced apart from each other in the second direction DR2. However, the present disclosure is not limited thereto.

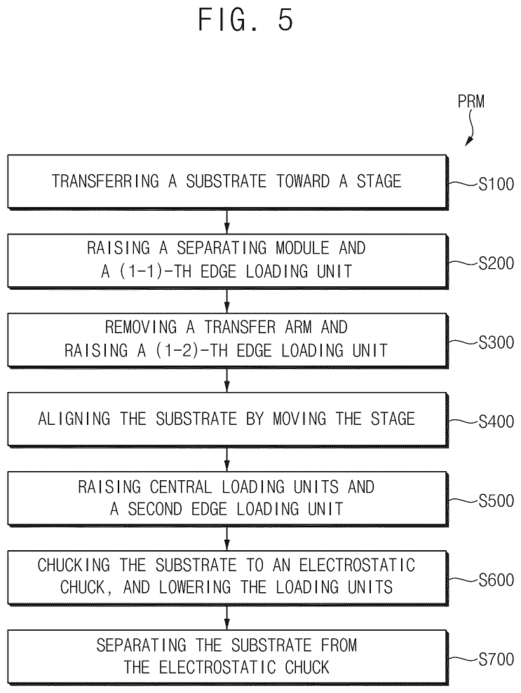

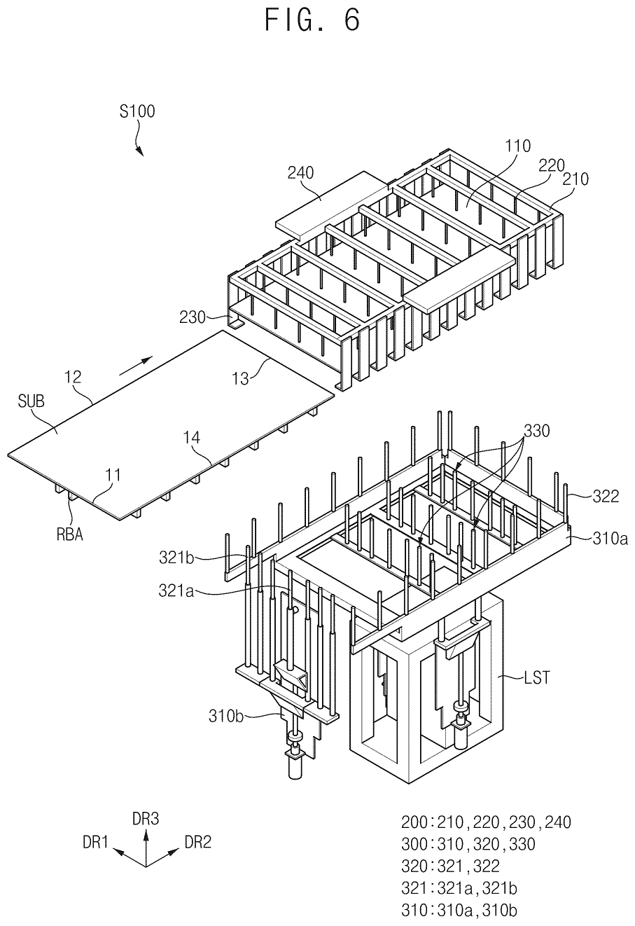

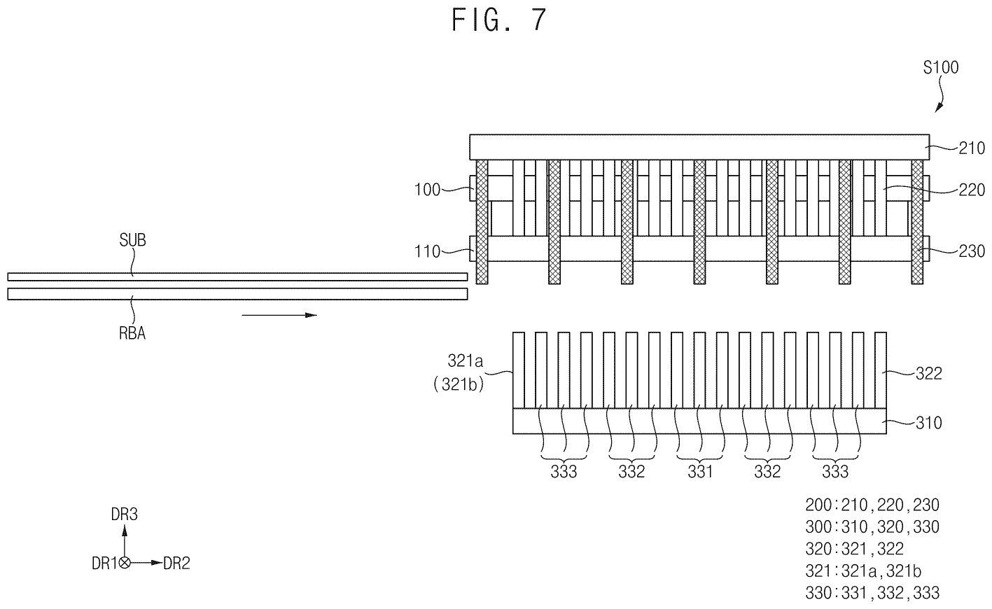

FIG. 5 is a flowchart illustrating a substrate processing method according to an embodiment of the present disclosure. FIGS. 6, 7, 8, 9, 10, 11, 12, 13, 14, 15, 16, 17, and 18 are views illustrating the substrate processing method of FIG. 5. In FIGS. 6, 8, 10, 12, and 14, the electrostatic chuck 110, which is illustrated in FIG. 2, is illustrated, and the stage 100, which is illustrated in FIG. 2, is not illustrated. As illustrated in FIG. 2, the push member 220 and the substrate holder 230 may be located inside the stage 100, but for convenience of description, the push member 220 and the substrate holder 230 are illustrated as being located outside the stage 100 in FIGS. 7, 9, 11, 13, 15, 16, 17, and 18.

Referring to FIGS. 2 and 5, a substrate processing method PRM according to an embodiment of the present disclosure may include transferring the substrate SUB toward the stage 100 (S100), raising the separating module 200 and the (1-1)-th edge loading unit 321a (S200), removing a transfer arm and raising the (1-2)-th edge loading unit 321b (S300), aligning the substrate SUB by moving the stage 100 (S400), raising the central loading units 330 and the second edge loading unit 322 (S500), chucking the substrate SUB to the electrostatic chuck 110, and lowering the loading units (S600), and separating the substrate SUB from the electrostatic chuck 110 (S700).

Referring to FIGS. 6 and 7, the substrate SUB may be transferred to be positioned under the stage 100 (S100). The stage 100 may include the electrostatic chuck 110.

The substrate SUB may be loaded on a transfer arm RBA. The transfer arm RBA may transfer the substrate SUB toward a lower surface of the stage 100. The substrate SUB may include a first side 11 extending in the first direction DR1, a second side 12 which contacts the first side 11 and extends in the second direction DR2, a third side 13 which extends parallel to the first side 11 and faces the first side 11, and a fourth side 14 which extends parallel to the second side 12 and faces the second side 12. In an embodiment, a length of the first side 11 may be smaller than a length of the second side 12. That is, the substrate SUB may have a rectangular shape with the first side 11 as a short side and the second side 12 as a long side in a plan view.

The separating module 200 may be disposed on the stage 100. The separating module 200 may include the first body portion 210, the push member 220, the substrate holder 230, and the coupling portion 240. The push member 220 may be connected to the first body portion 210. The push member 220 may protrude from the first body portion 210 toward the electrostatic chuck 110. The substrate holder 230 may be connected to the first body portion 210. The substrate holder 230 may be repeatedly disposed along the circumference of the first body portion 210. The substrate holder 230 may not be disposed at one of the first to fourth sides of the first body portion 210. That is, the substrate holder 230 may not be disposed at one of the first to fourth sides of the first body portion 210 so that the transfer arm RBA loaded with the substrate SUB may move under the stage 100.

The loading module 300 may be disposed under the stage 100. The loading module 300 may include the second body portion 310, the edge loading units 320, and the central loading units 330. The edge loading units 320 may include the first edge loading units 321 and the second edge loading units 322.

The second body portion 310 may include the first portion 310a and the second portion 310b. The first portion 310a of the second body portion 310 may have a rectangular shape with one side open in a plan view. The second portion 310b of the second body portion 310 may overlap the open side of the first portion 310a in a plan view.

The first edge loading units 321 may be connected to the second portion 310b of the second body portion 310. The first edge loading units 321 may protrude from the second portion 310b of the second body portion 310 toward the electrostatic chuck 110. The first edge loading units 321 may include the (1-1)-th edge loading unit 321a and the (1-2)-th edge loading unit 321b.

The second edge loading units 322 may be connected to the first portion 310a of the second body portion 310. The second edge loading units 322 may be repeatedly disposed along the circumference of the first portion 310a of the second body portion 310. The second edge loading units 322 may protrude from the first portion 310a of the second body portion 310 toward the electrostatic chuck 110.

The central loading units 330 may be connected to the first portion 310a of the second body portion 310. The central loading units 330 may be disposed inside the edge of the first portion 310a of the second body portion 310. The central loading units 330 may protrude from the first portion 310a of the second body portion 310 toward the electrostatic chuck 110.

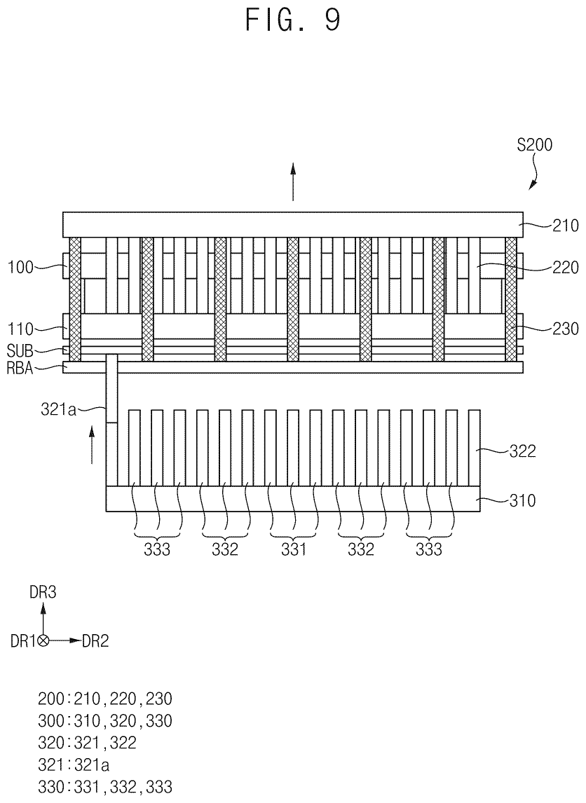

Referring to FIGS. 8 and 9, the separating module 200 and the (1-1)-th edge loading unit 321a may rise (S200).

The separating module 200 may move in the third direction DR3. In other words, the separating module driver (not illustrated) may raise the separating module 200 in a direction away from the substrate SUB. Accordingly, the substrate holder 230 may move in the third direction DR3 and directly contact the edge of the substrate SUB. In other words, the substrate holder 230 may support the edge of the substrate SUB. The substrate holder 230 may not support one of the first to fourth sides 11, 12, 13, and 14 of the substrate SUB. In an embodiment, for example, as illustrated in FIG. 8, the substrate holder 230 may support the second to fourth sides 12, 13, and 14 of the substrate SUB, and may not support the first side 11 of the substrate SUB.

The (1-1)-th edge loading unit 321a may move in the third direction DR3. Specifically, the second portion 310b of the second body portion 310 may rise toward the substrate SUB. Accordingly, the (1-1)-th edge loading unit 321a and the (1-2)-th edge loading unit 321b protruding from the second portion 310b of the second body portion 310 may rise toward the substrate SUB. In addition, the (1-1)-th edge loading unit 321a may rise toward the substrate SUB independently of the second portion 310b of the second body portion 310. That is, the (1-1)-th edge loading unit 321a may rise further toward the substrate SUB than the (1-2)-th edge loading unit 321b. The (1-1)-th edge loading unit 321a may press (or support) the first side 11 of the substrate SUB which is not supported by the substrate holder 230. The (1-1)-th edge loading unit 321a may pass through the transfer arm RBA and press the first side 11 of the substrate SUB. In an embodiment, the (1-1)-th edge loading unit 321a may rise simultaneously with the separating module 200.

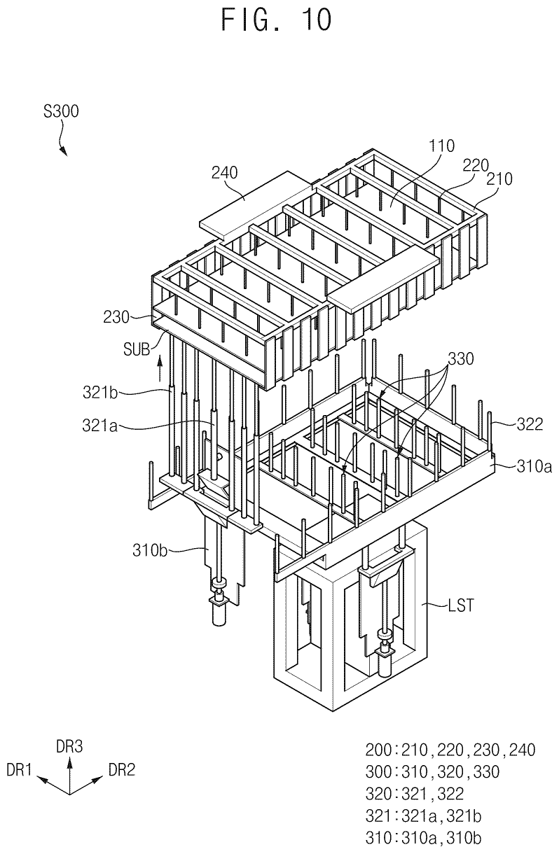

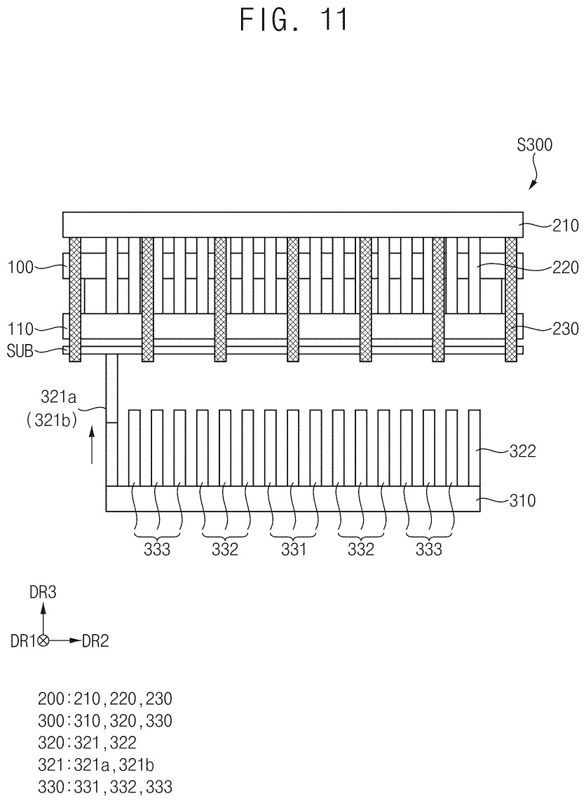

Referring to FIGS. 10 and 11, the transfer arm RBA is removed, and the (1-2)-th edge loading unit 321b may rise (S300).

The substrate SUB may be supported by the substrate holder 230 and the (1-1)-th edge loading unit 321a, and the transfer arm RBA may be retrieved (removed).

After the transfer arm RBA is retrieved, the (1-2)-th edge loading unit 321b may move in the third direction DR3. In other words, the (1-2)-th edge loading unit 321b may rise toward the substrate SUB. The (1-2)-th edge loading unit 321b may press (or support) the first side 11 of the substrate SUB which is not supported by the substrate holder 230.

Accordingly, the first side 11 of the substrate SUB may be supported by the (1-1)-th edge loading unit 321a and the (1-2)-th edge loading unit 321b, and the second to fourth sides 12, 13, and 14 of the substrate SUB may be supported by the substrate holder 230.

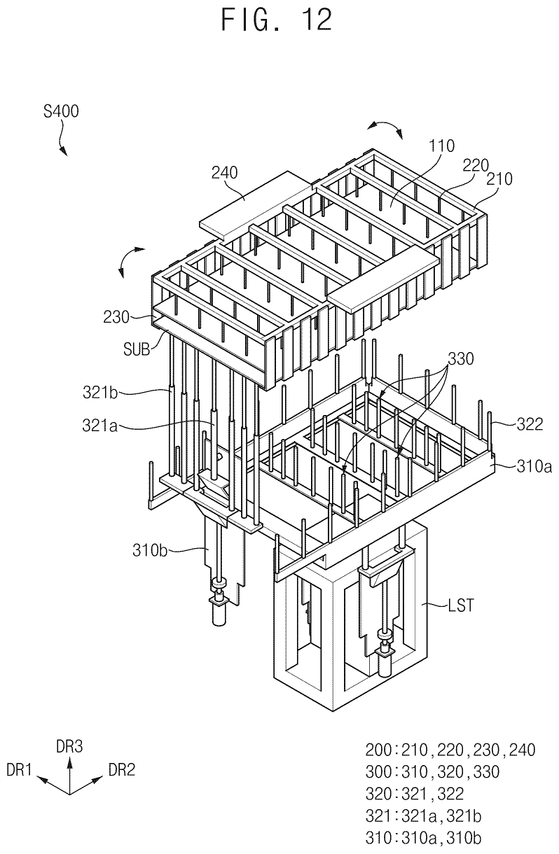

Referring to FIGS. 12 and 13, the position of the substrate SUB may be aligned by moving the stage 100 (S400).

A camera 400 may be disposed under the stage 100. In an embodiment, for example, the camera 400 may be disposed on the loading stage LST. The camera 400 may measure an alignment mark of the substrate SUB. In an embodiment, for example, the camera 400 may be a line scan camera or an area scan camera. The stage 100 may align the position of the substrate SUB, based on a position of the alignment mark. In an embodiment, for example, the stage 100 may be a UVW stage.

As the substrate SUB becomes larger in area, the substrate SUB may become misaligned during the process of transferring the substrate SUB to the stage 100. When the substrate SUB contacts loading units (e.g., the central loading units 330) while the substrate SUB is misaligned, the loading units may contact the cell area of the substrate SUB in which the display panel cells are disposed. Accordingly, a problem in which the display panel cells are damaged may occur.

To prevent the display panel cells from being damaged, the position of the substrate SUB may be aligned before the substrate SUB contacts the loading units. Since the first side 11 of the substrate SUB is supported by the first edge loading units 321, and the second to fourth sides 12, 13, and 14 of the substrate SUB is supported by the substrate holder 230, a process of aligning the substrate SUB may be performed before the substrate SUB contacts the loading units. Accordingly, the loading units may not contact the cell area of the substrate SUB in which the display panel cells are disposed, but may contact the dummy area of the substrate SUB which is subsequently removed. Accordingly, the problem of the display panel cells being damaged due to contact with the loading units may be effectively prevented.

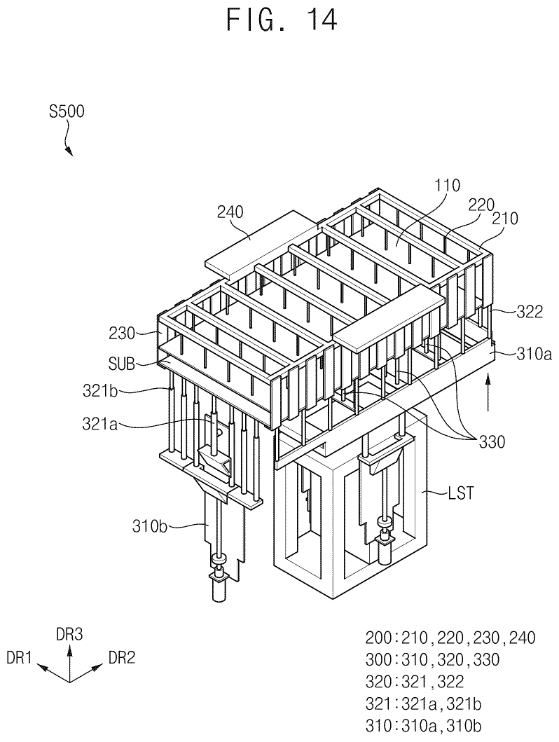

Referring to FIGS. 14, 15, 16, and 17, the central loading units 330 and the second edge loading units 322 may rise (S500).

As illustrated in FIGS. 15, 16, and 17, the central loading units 330 may include first central loading units 331, second central loading units 332, and third central loading units 333. The first central loading units 331 may overlap a central portion of the substrate SUB (e.g., a central portion in the second direction DR2) in a plan view. The second central loading units 332 may be spaced apart from the first central loading units 331 in the second direction DR2 and in a direction opposite to the second direction DR2. The third central loading units 333 may be spaced apart from the first central loading units 331 in the second direction DR2 and in the direction opposite to the second direction DR2, and farther from the first central loading units 331 than the second central loading units 332.

The second central loading units 332 and the third central loading units 333 may be disposed in a direction away from the central portion of the substrate SUB with respect to the first central loading units 331 (e.g., in the second direction DR2 or in the direction opposite to the second direction DR2). The second central loading units 332 may be closer to the central portion of the substrate SUB than the third central loading units 333. In other words, the third central loading units 333 may be closer to the edge of the substrate SUB than the second central loading units 332.

In an embodiment, the first central loading units 331 may be repeatedly disposed along the first direction DR1, the second central loading units 332 may be repeatedly disposed along the first direction DR1, and the second central loading units 332 may be positioned symmetrically with respect to the first central loading units 331. That is, the second central loading units 332 may be symmetrically positioned in the second direction DR2 and in the direction opposite to the second direction DR2 with respect to the first central loading units 331. In addition, the third central loading units 333 may be repeatedly disposed along the first direction DR1, and may be positioned symmetrically with respect to the first central loading units 331. That is, the third central loading units 333 may be positioned symmetrically in the second direction DR2 and in the direction opposite to the second direction DR2 with respect to the first central loading units 331.

In an embodiment, as illustrated in FIG. 15, the first central loading units 331 may rise before the second central loading units 332 and the third central loading units 333 rise. That is, the first central loading units 331 among the first to third central loading units 331, 332 and 333 may rise first toward the substrate SUB. Accordingly, the first central loading units 331 may first press the central portion of the substrate SUB toward the electrostatic chuck 110. In an embodiment, for example, the first central loading units 331 may include three first groups disposed in a row along the first direction DR1, and the first groups may be spaced apart from each other in the second direction DR2. However, the present disclosure is not limited thereto.

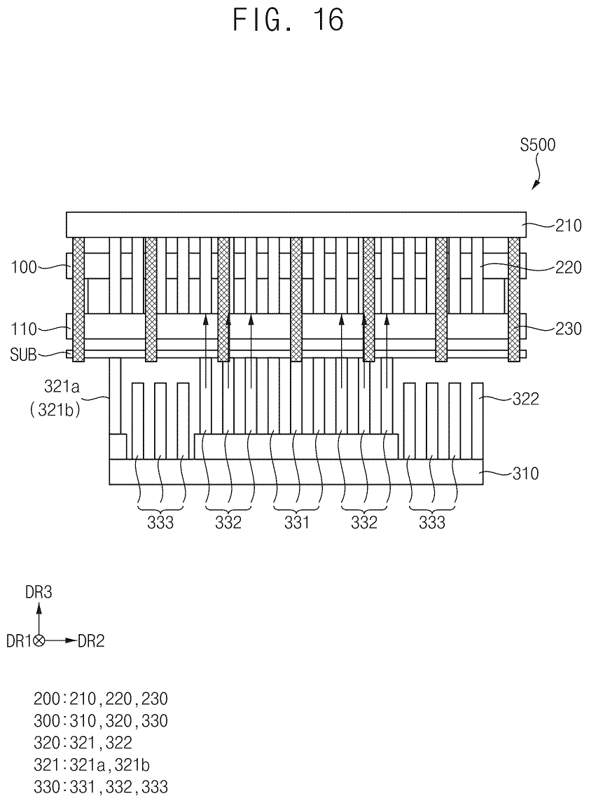

As illustrated in FIG. 16, the second central loading units 332 may rise a second time toward the substrate SUB. Accordingly, the second central loading units 332 may press a second time an area adjacent to the central portion of the substrate SUB toward the electrostatic chuck 110. In an embodiment, for example, the second central loading units 332 may include six second groups disposed in a row along the first direction DR1, and the second groups may be spaced apart from each other in the second direction DR2. However, the present disclosure is not limited thereto.

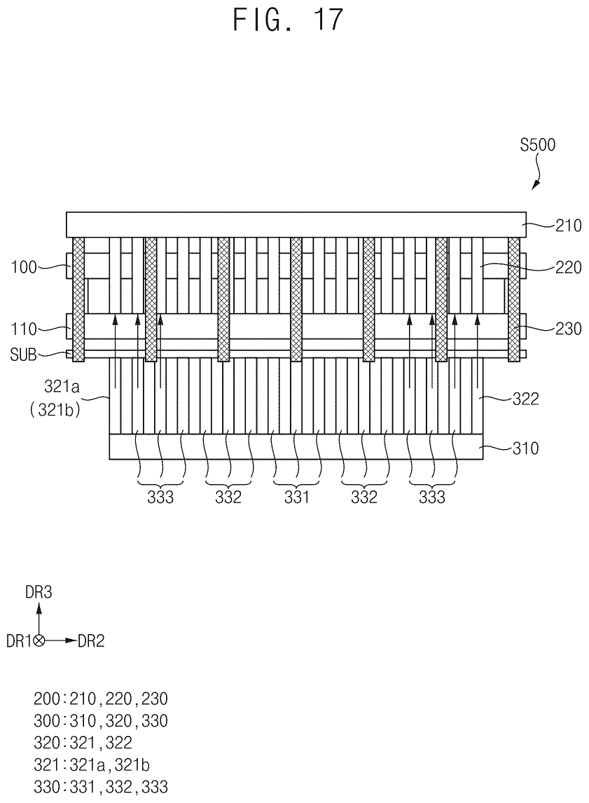

As illustrated in FIG. 17, the third central loading units 333 may rise a third time toward the substrate SUB. Accordingly, the third central loading units 333 may press a third time an area adjacent to the edge of the substrate SUB toward the electrostatic chuck 110. In an embodiment, for example, the third central loading units 333 may include six third groups disposed in a row along the first direction DR1, and the third groups may be spaced apart from each other in the second direction DR2. However, the present disclosure is not limited thereto.

That is, the central loading units 330 may be driven to rise such that the central portion of the substrate SUB has an upwardly convex curved surface. In other words, the first central loading units 331 which press the central portion of the substrate SUB may rise first, and the third central loading units 333 which press the area adjacent to the edge of the substrate SUB may rise last. As the central portion of the substrate SUB rises to have an upwardly convex curved surface, the substrate SUB may be prevented from sagging during rising toward the electrostatic chuck 110.

Accordingly, the first central loading units 331, the second central loading units 332, and the third central loading units 333 may press a portion of the substrate SUB which is positioned inside from the edge of the substrate SUB toward the electrostatic chuck 110.

The second edge loading units 322 may rise toward the substrate SUB. Accordingly, the second edge loading units 322 may press the edge of the substrate SUB toward the electrostatic chuck 110. Specifically, the second edge loading units 322 may press the second to fourth sides 12, 13, and 14 of the substrate SUB which are supported by the substrate holder 230. In an embodiment, the second edge loading units 322 may rise simultaneously with the third central loading units 333. However, the present disclosure is not limited to this, and the second edge loading units 322 may rise later than the third central loading units 333.

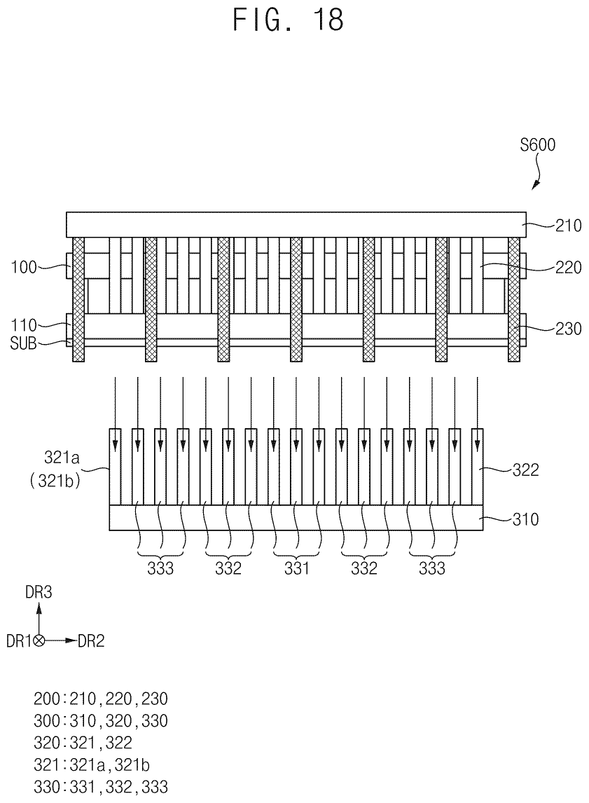

Referring to FIG. 18, the substrate SUB may be chucked in the electrostatic chuck 110, and the loading units may descend (S600).

The substrate SUB may be pressed by the edge loading units 320 and the central loading units 330 to rise toward the electrostatic chuck 110. The electrostatic chuck 110 may chuck the substrate SUB with electrostatic force. Accordingly, the substrate SUB may be fixedly adsorbed to the lower surface of the electrostatic chuck 110. That is, the substrate SUB may be fixed with a surface that is irradiated by a laser beam facing downward.

After the substrate SUB is chucked to the electrostatic chuck 110, the edge loading units 320 and the central loading units 330 may descend in a direction away from the substrate SUB. In this case, the edge loading units 320 and the central loading units 330 may descend simultaneously.

After the substrate SUB is chucked to the electrostatic chuck 110, the stage 100 may transfer the substrate SUB toward the laser unit (e.g., the laser unit LAS of FIG. 1). A process of etching the substrate SUB may be performed by irradiating a laser beam to the substrate SUB by the laser unit.

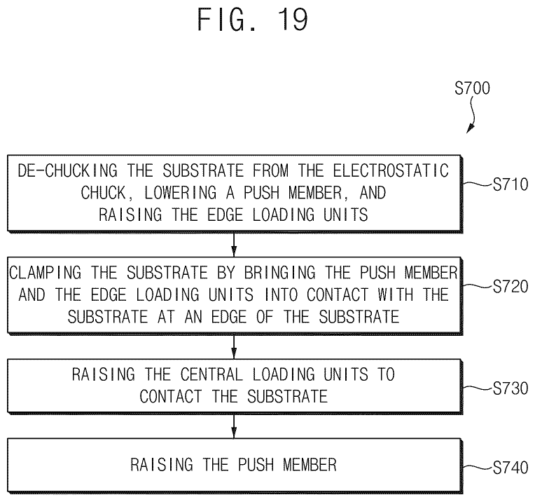

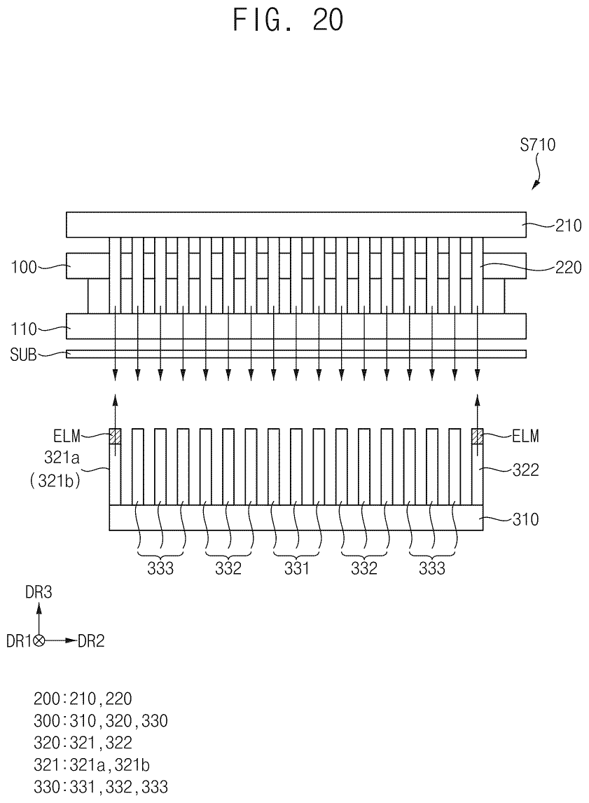

FIG. 19 is a flowchart illustrating separating a substrate from an electrostatic chuck included in the substrate processing method of FIG. 5. FIGS. 20, 21, 22, and 23 are cross-sectional views illustrating the separating the substrate SUB from the electrostatic chuck of FIG. 19. In FIGS. 20, 21, 22, and 23, the substrate holder 230, which is illustrated in FIGS. 6 and 7, is not illustrated. As illustrated in FIG. 2, the push member 220 may be located inside the stage 100, but for convenience of description, the push member 220 is illustrated as being located outside the stage 100 in FIGS. 20, 21, 22, and 23.

Referring to FIGS. 2 and 19, the separating the substrate SUB from the electrostatic chuck 110 (S700) may include de-chucking the substrate SUB from the electrostatic chuck 110, lowering the push member 220, and raising the edge loading units 320 (S710), clamping the substrate SUB by bringing the push member 220 and the edge loading units 320 into contact with the substrate SUB at the edge of the substrate SUB (S720), raising the central loading units 330 to contact the substrate SUB (S730), and raising the push member 220 (S740).

Referring to FIG. 20, the substrate SUB may be de-chucked from the electrostatic chuck 110, the push member 220 may descend, and the edge loading units 320 may rise (S710).

After the substrate SUB is etched by the laser unit, the stage 100 may transfer the substrate SUB toward the loading module 300. The substrate SUB may move to overlap the edge loading units 320 and the central loading units 330 in a plan view, and the substrate SUB may be de-chucked from the electrostatic chuck 110. At this time, when chucking and de-chucking between the substrate SUB and the electrostatic chuck 110 are repeated, the substrate SUB may not separate from the electrostatic chuck 110 due to residual electrostatic charge between the substrate SUB and the electrostatic chuck 110. When the substrate SUB is not separated from the electrostatic chuck 110, the push member 220 may press the substrate SUB toward the loading module 300.

Specifically, the separating module driver may lower the separating module 200 toward the substrate SUB. That is, although not illustrated in FIG. 20, the first body portion 210 and the substrate holder 230 may descend together with the push member 220. As the push member 220 descends toward the substrate SUB, the push member 220 may press the substrate SUB through a through hole defined in the electrostatic chuck 110. The push member 220 may be repeatedly disposed along the first direction DR1 and the second direction DR2. Accordingly, the push member 220 may press the substrate SUB over the entire area of the substrate SUB.

In an embodiment, the push member 220 may include the sensor (e.g., the sensor 222 of FIG. 4) which measures an electrostatic force between the substrate SUB and the electrostatic chuck 110. Specifically, the sensor may measure the amount of residual electrostatic charge between the substrate SUB and the electrostatic chuck 110 after de-chucking the substrate SUB from the electrostatic chuck 110.

In an embodiment, the separating module 200 may further include a control portion which controls the speed of the push member 220 in response to the electrostatic force between the substrate SUB and the electrostatic chuck 110. Specifically, the control portion may control the speed of the push member 220 in response to the amount of residual electrostatic charge between the substrate SUB and the electrostatic chuck 110 which is measured by the sensor. Accordingly, even when the substrate SUB is not separated from the electrostatic chuck 110 due to the residual electrostatic charge between the substrate SUB and the electrostatic chuck 110, the substrate SUB may be effectively separated from the electrostatic chuck 110 by the push member 220 pressing the substrate SUB towards the loading module 300.

The edge loading units 320 may rise toward the substrate SUB. In an embodiment, the raising the edge loading units 320 toward the substrate SUB may be performed simultaneously with the lowering the push member 220 toward the substrate SUB. The edge loading units 320 may include the first edge loading units 321 and the second edge loading units 322.

Referring to FIG. 21, the push member 220 and the edge loading units 320 may contact the substrate SUB at the edge of the substrate SUB and may clamp the substrate SUB (S720).

As the push member 220 descends toward the substrate SUB, the push member 220 may contact the entire area of the substrate SUB. As the edge loading units 320 rise toward the substrate SUB, the edge loading units 320 may contact the edge of the substrate SUB. That is, at the edge of the substrate SUB, the push member 220 may contact an upper surface of the substrate SUB, and the edge loading units 320 may contact a lower surface of the substrate SUB.

Accordingly, the push member 220 and the edge loading units 320 may clamp the edge of the substrate SUB. As a result, when loading the substrate SUB on the edge loading units 320 and the central loading units 330, a problem of the substrate SUB slipping may be effectively prevented.

In an embodiment, an elastic member ELM may be disposed at an end of each of the edge loading units 320 in contact with the substrate SUB. Accordingly, in the clamping the substrate SUB, the elastic member ELM may relieve an impact applied to the substrate SUB. The elastic member ELM may include elastic material such as rubber.

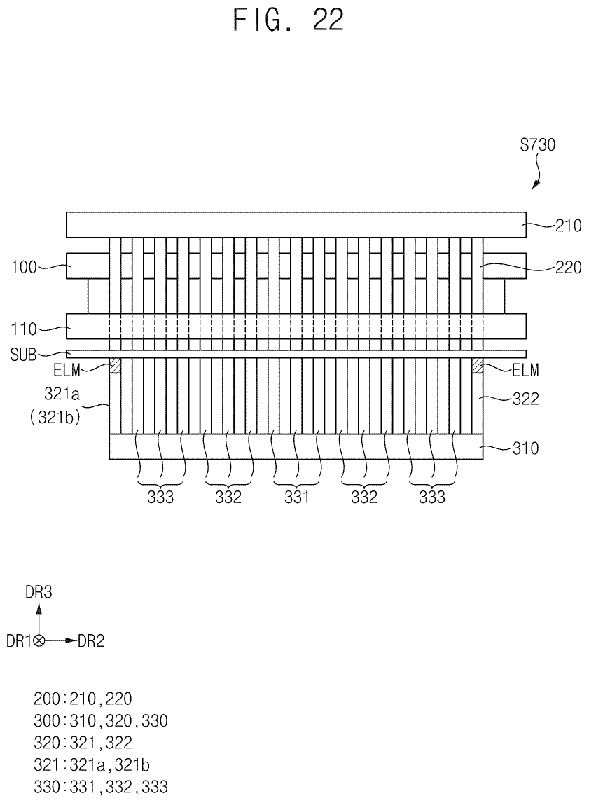

Referring to FIG. 22, the central loading units 330 may rise and contact the substrate SUB (S730).

After the push member 220 and the edge loading units 320 clamp the edge of the substrate SUB, the central loading units 330 may rise toward the substrate SUB. Accordingly, the central loading units 330 may contact the lower surface of the substrate SUB positioned inside from the edge of the substrate SUB. As a result, the substrate SUB may be loaded on the edge loading units 320 and the central loading units 330.

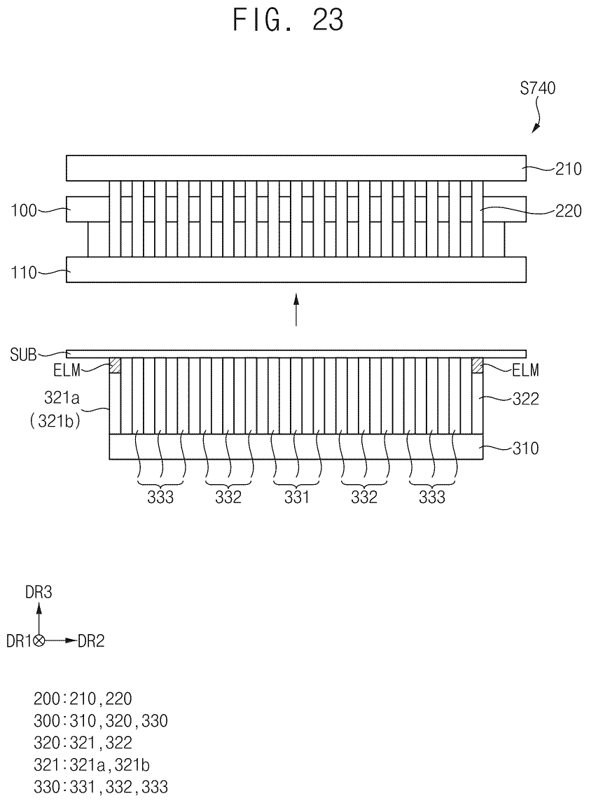

Referring to FIG. 23, the substrate SUB may be supported by the loading units, and the push member 220 may rise (S740).

After the substrate SUB is loaded on the edge loading units 320 and the central loading units 330, the separating module driver may raise the separating module 200 in a direction away from the substrate SUB. That is, the first body portion 210 and the substrate holder 230 may rise together with the push member 220. As a result, the substrate SUB may be separated from the electrostatic chuck 110.

The present disclosure may be applied to various display devices. For example, the present disclosure is applicable to various display devices such as display devices for vehicles, ships and aircraft, portable communication devices, display devices for exhibition or information transmission, medical display devices, and the like.

The foregoing is illustrative of the embodiments of the present disclosure, and is not to be construed as limiting thereof. Although a few embodiments have been described with reference to the figures, those skilled in the art will readily appreciate that many variations and modifications may be made therein without departing from the spirit and scope of the present disclosure as defined in the appended claims.

What is claimed is:

1. A substrate processing apparatus, the apparatus comprising:
a stage including an electrostatic chuck, which chucks a substrate;
a separating module disposed on the stage and including a push member, which separates the substrate from the electrostatic chuck, and a substrate holder, which supports an edge of the substrate; and
a loading module disposed under the stage and including a plurality of edge loading units, which press the edge of the substrate toward the electrostatic chuck, and a plurality of central loading units, which press a portion of the substrate positioned inside from the edge of the substrate toward the electrostatic chuck.

2. The apparatus of claim 1, wherein when the push member separates the substrate from the electrostatic chuck, the push member presses the substrate toward the loading module.

3. The apparatus of claim 1, wherein the push member includes a sensor, which measures an electrostatic force between the substrate and the electrostatic chuck.

4. The apparatus of claim 3, wherein the separating module further includes a control portion, which controls a speed of the push member in response to the electrostatic force.

5. The apparatus of claim 1, further comprising:
a camera disposed under the stage and which measures an alignment mark of the substrate,
wherein the stage is configured to align the substrate based on a position of the alignment mark.

6. The apparatus of claim 1, wherein the substrate includes a first side extending in a first direction, a second side which contacts the first side and extends in a second direction intersecting the first direction, a third side which extends parallel to the first side and faces the first side, and a fourth side which extends parallel to the second side and faces the second side, and
the substrate holder does not support one of the first to fourth sides.

7. The apparatus of claim 6, wherein the plurality of edge loading units include:
a plurality of first edge loading units, which press the one side of the substrate not supported by the substrate holder; and
a plurality of second edge loading units, which press sides of the substrate supported by the substrate holder.

8. The apparatus of claim 1, wherein the substrate includes a first side extending in a first direction and a second side which contacts the first side and extends in a second direction intersecting the first direction,
a length of the first side is smaller than a length of the second side, and
the plurality of central loading units includes a plurality of first central loading units, which press a central portion of the substrate, and a plurality of second central loading units, which are spaced apart from the plurality of first central loading units in the second direction and in a direction opposite to the second direction.

9. The apparatus of claim 8, wherein the plurality of first central loading units are repeatedly disposed along the first direction,
the plurality of second central loading units are repeatedly disposed along the first direction, and
the plurality of second central loading units are positioned symmetrical with respect to the plurality of first central loading units.

10. The apparatus of claim 1, further comprising:
an elastic member disposed at an end of each of the plurality of edge loading units which contacts the substrate.

11. A substrate processing method, the method comprising:
transferring a substrate to be positioned under a stage, which includes an electrostatic chuck;
raising a separating module, which is positioned on the stage and includes a push member and a substrate holder, and supporting an edge of the substrate with the substrate holder;
aligning a position of the substrate by moving the stage;
raising a plurality of central loading units, which are positioned under the stage, to press a portion of the substrate positioned inside from the edge of the substrate, and raising a plurality of edge loading units, which are positioned under the stage, to press the edge of the substrate;
chucking the substrate to the electrostatic chuck; and
separating the substrate from the electrostatic chuck by de-chucking the substrate from the electrostatic chuck and by pressing the substrate with the push member.

12. The method of claim 11, wherein the separating of the substrate from the electrostatic chuck includes:
measuring an electrostatic force between the substrate and the electrostatic chuck; and
controlling a speed of the push member in response to the electrostatic force.

13. The method of claim 12, wherein the push member includes a sensor, which measures the electrostatic force, and
the separating module further includes a control portion, which controls the speed of the push member in response to the electrostatic force.

14. The method of claim 11, wherein the substrate includes a first side extending in a first direction, a second side which contacts the first side and extends in a second direction intersecting the first direction, a third side which extends parallel to the first side and faces the first side, and a fourth side which extends parallel to the second side and faces the second side, and
the substrate holder does not support one of the first to fourth sides in the supporting of the edge of the substrate with the substrate holder.

15. The method of claim 14, further comprising:
raising some of the plurality of edge loading units to support the one side of the substrate which is not supported by the substrate holder before the aligning of the position of the substrate.

16. The method of claim 11, wherein the substrate includes a first side extending in a first direction and a second side which contacts the first side and extends in a second direction intersecting the first direction,
a length of the first side is smaller than a length of the second side, and
the plurality of central loading units includes a plurality of first central loading units, which press a central portion of the substrate, and a plurality of second central loading units, which are spaced apart from the plurality of first central loading units in the second direction and in a direction opposite to the second direction.

17. The method of claim 16, wherein the plurality of first central loading units are repeatedly disposed along the first direction,
the plurality of second central loading units are repeatedly disposed along the first direction, and
the plurality of second central loading units are positioned symmetrical with respect to the plurality of first central loading units.

18. The method of claim 16, wherein the plurality of first central loading units rise before the plurality of second central loading units rise in the raising of the plurality of central loading units.

19. The method of claim 11, wherein the separating of the substrate from the electrostatic chuck includes:
lowering the push member and raising the plurality of edge loading units toward the substrate;
clamping the substrate by bringing the push member and the plurality of edge loading units into contact with the substrate at the edge of the substrate; and
raising the plurality of central loading units to contact the substrate.

20. The method of claim 19, wherein in the clamping of the substrate,
an impact applied to the substrate is relieved by an elastic member disposed at an end of each of the plurality of edge loading units, which contacts the substrate.
